(19) United States
(12) Patent Application Publication
(10) Pub. No.: US 2020/0218775 A1
(43) Pub. Date: Jul. 9, 2020

(54) METHODS AND CIRCUITRY FOR BOOSTING THE THROUGHPUT OF RECURSIVE SYSTEMS

(71) Applicant: Intel Corporation, Santa Clara, CA (US)

(72) Inventors: Dan Pritsker, San Diego, CA (US); Colman Chungling Cheung, San Diego, CA (US)

(73) Assignee: Intel Corporation, Santa Clara, CA (US)

(21) Appl. No.: 16/820,954

(22) Filed: Mar. 17, 2020

(51) Int. Cl. G06F 17/14; H03K 19/17724; H03K 19/1776

(52) U.S. Cl. CPC G06F 17/147; H03K 19/1776; H03K 19/17724; G06F 17/142

(57) ABSTRACT

A computing system may include a recursive circuit with a feedback path. The recursive circuit may be provided with an orthogonal transformation circuit configured to decompose a single input data stream into independent components that can then be processed by the recursive circuit. The recursive circuit may further be provided with an inverse orthogonal transformation circuit configured to recombine the independent components that have been processed by the recursive circuit into a single output data stream. Operated in this way, the throughput of the recursive system can be optimized such that the recursive circuit is capable of outputting samples at the maximum clock frequency of the underlying computing system.

### BACKGROUND

A digital implementation of a recursive system typically includes a processing pipeline with a feedforward path and a feedback path. The length of the processing pipeline and, in particular, the latency of the feedback path, are the fundamental factors limiting the throughput of the recursive system.

A digital accumulator block represents a simple example of such recursive system. In an accumulator block, an input number must be added with the result of a previous addition. In practice, however, it often takes more than a single clock cycle to perform each addition operation (especially for floating-point numbers). As a result, the expected result from the prior addition may not yet be ready in the next cycle, and the simple accumulated result will be erroneous.

It is within such context that the embodiments described herein arise.

### BRIEF DESCRIPTION OF THE DRAWINGS

FIG. 1 is a diagram of an illustrative programmable integrated circuit in accordance with an embodiment.

FIG. 2 is a diagram of an illustrative integrated circuit that includes recursive/iterative circuits in accordance with an embodiment.

FIG. 3A is a diagram of an illustrative systolic array in accordance with an embodiment.

FIG. 3B is a diagram of an illustrative cell within the systolic array of FIG. 3A in accordance with an embodiment.

FIG. 4 is a diagram of a recursive system with illustrative circuitry configured to perform pre-processing by decomposing a single data stream into independent components and to perform post-processing by recombining the independent components in accordance with an embodiment.

FIG. 5 is a diagram showing illustrative pre/post transformation circuits that may be implemented in a recursive system in accordance with an embodiment.

FIG. 6 is a diagram showing how a fast Fourier transform (FFT) circuit can be used to channelize a single data stream into multiple independent spectral components in accordance with an embodiment.

FIG. 7 is a flow chart of illustrative steps for operating a recursive system of the type shown in connection with FIGS. 4-6 in accordance with an embodiment.

### DETAILED DESCRIPTION

The present embodiments relate to a recursive system with a feedback path having a feedback latency. The recursive system may be provided with pre-processing circuitry configured to decompose a single input data stream into corresponding principal and independent components using a predetermined mathematical transformation. The recursive system may further be provided with post-processing circuitry configured to perform the inverse mathematical transformation (i.e., the inverse operation of the predetermined mathematical transform), which converts the decomposed samples back to the original domain.

A recursive system configured in this way provides a tangible technical improvement to computer technology by allowing the iterative system to support situations where the input streams cannot be presented as independent channels while ensuring that the system maintains maximum throughput by hiding the any inefficiency due to the feedback latency. It will be recognized by one skilled in the art, that the present exemplary embodiments may be practiced without some or all of these specific details. In other instances, well-known operations have not been described in detail in order not to unnecessarily obscure the present embodiments.

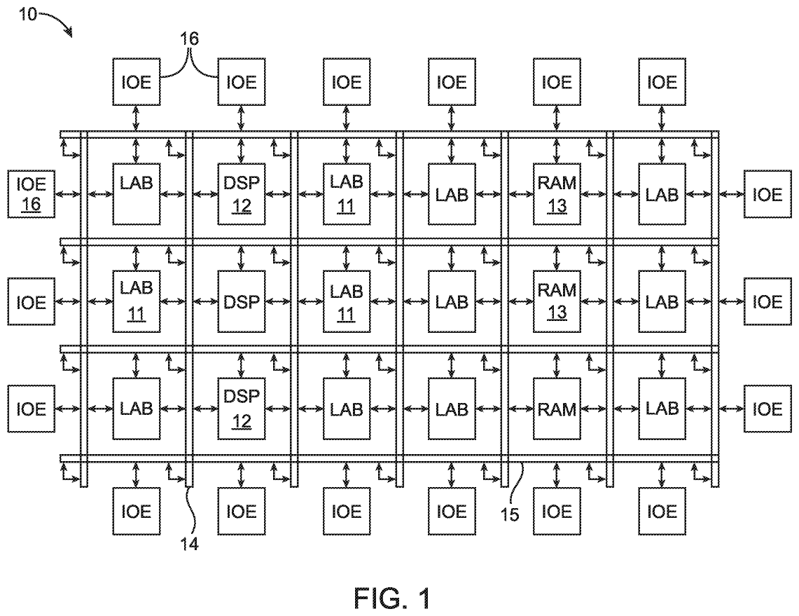

Recursive systems (sometimes referred to as “iterative” systems) are often implemented on a programmable integrated circuit. FIG. 1 is a diagram of a programmable integrated circuit 10 (e.g., sometimes referred to as a programmable logic device, a field-programmable gate array or “FPGA”, etc.). As shown in FIG. 1, programmable logic device 10 may include a two-dimensional array of functional blocks, including logic array blocks (LABs) 11 and other functional blocks such as random access memory (RAM) blocks 13 and specialized processing blocks such as digital signal processing (DSP) blocks 12 that are partly or fully hardwired to perform one or more specific tasks such as mathematical/arithmetic operations.

Functional blocks such as LABs 11 may include smaller programmable regions (e.g., logic elements, configurable logic blocks, or adaptive logic modules) that receive input signals and perform custom functions on the input signals to produce output signals. Device 10 may further include programmable routing fabric that is used to interconnect LABs 11 with RAM blocks 13 and DSP blocks 12. The combination of the programmable logic and routing fabric sometimes referred to as “soft” logic, whereas the DSP blocks are sometimes referred to as “hard.” logic. The type of hard logic on device 10 is not limited to DSP blocks and may include other types of hard logic. Adders/subtractors, multipliers, dot product computation circuits, and other arithmetic circuits which may or may not be formed as part of a DSP block 12 may sometimes be referred to collectively as arithmetic logic.

Programmable logic device 10 may contain programmable memory elements for configuring the soft logic. Memory elements may be loaded with configuration data (also called programming data) using input/output elements (IOEs) 16. Once loaded, the memory elements provide corresponding static control signals that control the operation of one or more LABs 11, programmable routing fabric, and optionally DSPs 12 or RAMs 13. In a typical scenario, the outputs of the loaded memory elements are applied to the gates of metal-oxide-semiconductor transistors (e.g., pass transistors) to turn certain transistors on or off and thereby configure the logic in the functional block including the routing paths.

Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc. The logic gates and multiplexers that are part of the soft logic, configurable state machines, or any general logic component not having a single dedicated purpose on device 10 may be referred to collectively as “random logic.”

The memory elements may use any suitable volatile and/or non-volatile memory structures such as random-access-memory (RAM) cells, fuses, antifuses, programmable read-only-memory memory cells, mask-programmed and laser-programmed structures, mechanical memory devices (e.g., including localized mechanical resonators), mechanically operated RAM (MORAM), programmable metallization cells (PMCs), conductive-bridging RAM (CBRAM), resistive memory elements, combinations of these structures, etc. Because the memory elements are loaded with configuration data during programming, the memory elements are sometimes referred to as configuration memory, configuration RAM (CRAM), configuration memory elements, or programmable memory elements.

In addition, programmable logic device 10 may use input/output elements (IOEs) 16 to drive signals off of device 10 and to receive signals from other devices. Input/output elements 16 may include parallel input/output circuitry, serial data transceiver circuitry, differential receiver and transmitter circuitry, or other circuitry used to connect one integrated circuit to another integrated circuit. As shown, input/output elements 16 may be located around the periphery of the chip. If desired, the programmable logic device may have input/output elements 16 arranged in different ways.

The routing fabric (sometimes referred to as programmable interconnect circuitry) on PLD 10 may be provided in the form of vertical routing channels 14 (i.e., interconnects formed along a vertical axis of PLD 10) and horizontal routing channels 15 (i.e., interconnects formed along a horizontal axis of PLD 10), each routing channel including at least one track to route at least one wire. If desired, routing wires may be shorter than the entire length of the routing channel. A length L wire may span L functional blocks. For example, a length four wire may span four functional blocks. Length four wires in a horizontal routing channel may be referred to as “H4” wires, whereas length four wires in a vertical routing channel may be referred to as “V4” wires.

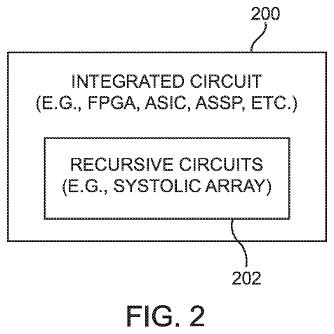

Furthermore, it should be understood that the present embodiments may be implemented in any integrated circuit. FIG. 2 is a diagram of an illustrative integrated circuit die 200. Integrated circuit 200 may, for example, be a programmable integrated circuit such as device 10 of FIG. 1, a central processing unit (CPU), a graphics processing unit (GPU), an application-specific integrated circuit (ASIC), an application specific standard product (ASSP), a microcontroller, a microprocessor, etc. Examples of programmable integrated circuits include programmable logic devices (PLDs), field programmable gate arrays (FPGAs), programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), and complex programmable logic devices (CPLDs), just to name a few.

As shown in FIG. 2, integrated circuit may include circuits such as recursive circuits 202. Recursive circuits (e.g., circuits that are configured to perform many iterations of one or more operations, that have one or more feedback paths, and/or that have data dependencies on prior states) are often used in an adaptive beamforming application, which involves performing a spatial filtering process in sensor arrays for directional transmission or reception. A beamforming circuit may include a phased array that linearly combines signals from a plurality of sensor elements while suppressing jamming signals in the environment.

In general, adaptive beamforming may be applied to a variety of applications, such as military applications of sonar and radar, wireless communication in commercial networks, radio applications, acoustic noise cancelling applications, microphone array speech processing, etc. The examples above in which recursive circuits are used to support adaptive beamforming applications are merely illustrative and are not meant to limit the scope of the present embodiments. In general, recursive circuits 202 may be included in any type of data computing system.

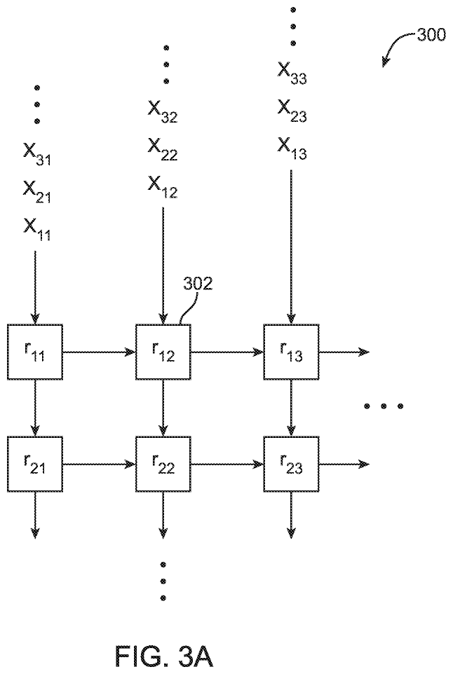

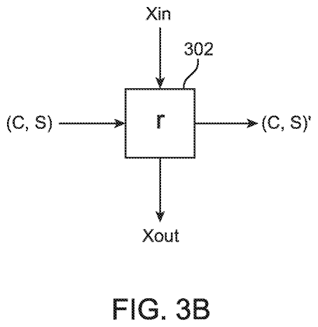

One example of a recursive circuit is a systolic array. FIG. 3A is a diagram of an illustrative systolic array 300. In general, a systolic array is a homogeneous mesh-like network of processing elements (sometimes referred to as “cells” or “nodes”) typically arranged in a 1-dimensional, 2-dimensional, or 3-dimensional layout. The processing cells are configured to perform some sequence of operations on data flowing between the associated nearest neighbors.

In the example of FIG. 3A, systolic array 300 may include a first column of cells (e.g., cells r₁₁ and r₂₁) configured to receive inputs X₁₁, X₂₁, X₃₁, and so on, a second column of cells (e.g., cells r₁₂ and r₂₂) configured to receive inputs X₁₂, X₂₂, X₃₂, and so on, and a third column of cells (e.g., cells r₁₃ and r₂₃) configured to receive inputs X₁₃, X₂₃, X₃₃, and so on. In FIG. 3A, the two by three grid of processing elements (“PEs”) is merely illustrative. In general, systolic array 300 may include any suitable number of processing elements (e.g., hundreds or thousands of PEs) arranged in any suitable number of rows, columns, and dimensions.

FIG. 3B is a diagram of an illustrative cell 302 within systolic array 300. As shown in FIG. 3B, cell 302 may have a first input terminal configured to receive input signal Xin, a second input terminal configured to receive input signals (C,S), a first output terminal on which corresponding output signals (C,S)′ are provided, and a second output terminal on which output signal Xout is provided. All input and/or output signals may be complex numbers. For instance, output signal Xout may be a function of C, Xin, and the previous/current state of cell 302. Moreover, the new/next state of cell 302 may be a function of input signals (C,S), Xin, and the prior/current state of cell 302. Since the next state of cell 302 is computed from its previous state, cell 302 needs to finish computing the current state information before the new input signals arrive. Functions such as these create large feedback loops in the overall recursive system, which can potentially deteriorate or limit the performance of the system.

One conventional way to solve the feedback latency in iterative systems is to decrease the input throughput by the ratio of the feedback path latency L_feedback. In other words, the user will throttle the input speed by a factor of L_feedback. This technique will produce correct system behavior, but the throughput of such system will be decimated by the input throttling ratio. In systems with feedback paths with tens of clock cycle latency, the resulting decrease in system throughput will be more than 10×, making the resulting system incredibly inefficient.

Another conventional way to solve the feedback latency problem is to stagger different independent channels along the L_feedback clock cycles (i.e., to interleave the independent channel inputs over time). This technique requires the iterative system to present data patterns with N completely independent data streams, where N must be greater than or equal to L_feedback for maximum efficiency. This technique is, however, application dependent and requires a multichannel configuration with N independent input channels. Unfortunately, many applications simply lack the concept or nature of multi-channel input data streams.

Yet another traditional way of solving the feedback latency problem involves unfolding the processing pipeline by a degree proportional to L_feedback. In the classical example of a floating-point accumulator, the system outputs partial sums into a shift register, and the parallel outputs of the shift register are summed in parallel using an explicit adder tree. This technique, however, can only be implemented in very simple iterative circuits. It is very challenging to convert complex iterative systems into such unfolded structure. Even in simple accumulator functions, the shift register and adder tree structure result in a large compute footprint, let alone more complex operations like dividing, trigonometric functions, or square roots which would make such implementation practically infeasible.

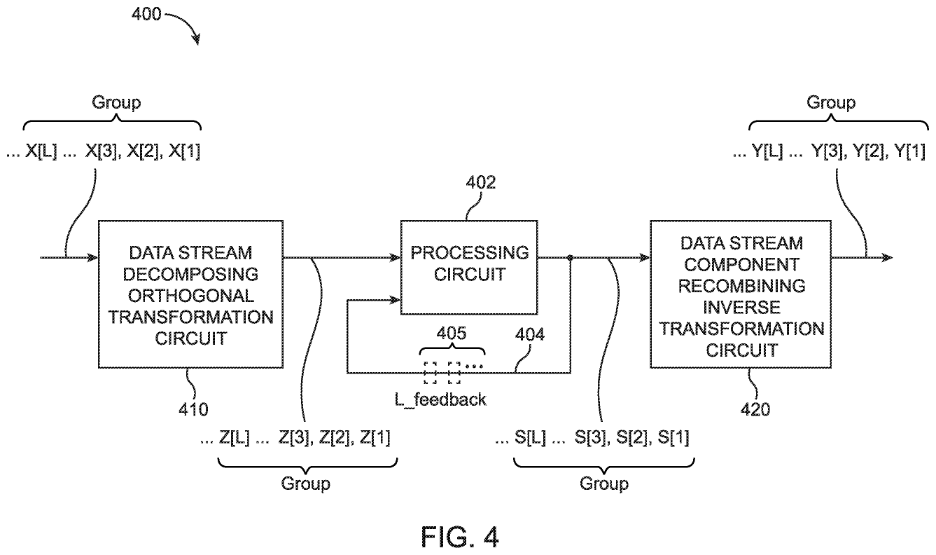

In accordance with an embodiment, FIG. 4 illustrative a recursive/iterative system such as system 400 that is capable of processing incoming data using the maximum clock frequency allowed by the underlying integrated circuit without requiring the system to have naturally independent input data streams. In other words, if the integrated circuit die on which system 400 is implemented has an operating clock rate of 500 MHz, then the recursive system 400 should be able to process 500 million samples per second per single data pipeline. System 400 may be part of recursive circuitry that is implemented on any type of integrated circuit die (see, e.g., circuit 202 in FIG. 2).

As shown in FIG. 4, system 400 may include a processing circuit 402 having an associated feedback path 404 with feedback latency L_feedback, a pre-processing circuit such as data stream decomposing orthogonal transformation circuit 410 inserted at the input of processing circuit 402, and a post-processing circuit such as data stream component recombining inverse transformation circuit 420 inserted at the output of processing circuit 402. System 400 may receive a single data stream {X[1], X[2], X[3], . . . , X[L], . . . }. The single data stream may be organized into groups of data, where each group has a group length “L”.

Pre-processing circuit 410 may be configured to decompose, break, or channelize the received input data stream into independent/orthogonal components using some predetermined mathematical transformation algorithm. In the example of FIG. 4, circuit 410 may transform the input data stream into corresponding decomposed components {Z[1], Z[2], Z[3], . . . , Z[L], . . . }, where each Z component within a group of size L are completely independent components (e.g., Z[1] is orthogonal with respect to Z[2:L], Z[2] is orthogonal with respect to Z[1,3:L], Z[3] is orthogonal with respect to Z[1,2,4:L], etc.). The decomposed components may be processed by circuit 402 to generate corresponding processed components {S[1], S[2], S[3], . . . , S[L], . . . }.

Post-processing circuit 420 may be configured to receive the processed components S[i] from circuit 402 and to recombine the processed components back to the original input domain using an inverse mathematical transformation algorithm. In other words, the output data stream recombination circuit 420 may perform a corresponding inverse transform of the initial transformation provided by the input data stream decomposition circuit 410. Circuit 420 may transform or convert the output data stream into a corresponding output data stream {Y[1], Y[2], Y[3], . . . , Y[L], . . . }, where each Y[i] component within a group of size L are no longer completely independent/orthogonal components.

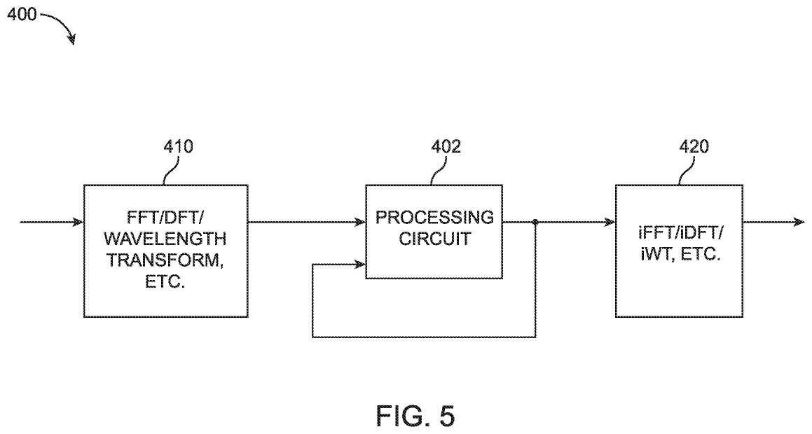

FIG. 5 is a diagram showing exemplary pre/post transformation circuits that may be implemented in recursive system 400. As shown in the example of FIG. 5, the pre-processing circuit 410 may be implemented as a fast Fourier transform (FFT) circuit, whereas the post-processing circuit 420 may be implemented as an inverse fast Fourier transform (iFFT) circuit. Configured in this way, the FFT circuit 410 may operate as an input stream channelizer (e.g., an analysis filter bank circuit) that decomposes a wideband input data stream into individual independent spectral components. For example, given an input signal that is sampled at 500 mega samples per second and assuming the underlying integrated circuit device is capable of running at 500 MHz, the FFT channelizer 410 may be able to channelize the input waveform into four independent/orthogonal streams each running at 125 mega samples per second to help recover the maximum possible system throughput that would otherwise have been lost due to the feedback latency.

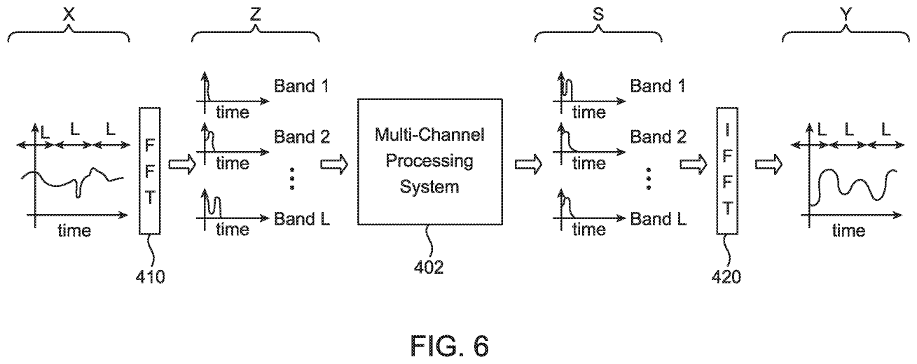

Conversely, the iFFT circuit 420 may operate as an inverse data stream channelizer (e.g., a synthesis filter bank circuit) that reconstructs the wideband signal by recombining from the individual spectral components. The use of an analysis/synthesis filter bank pair can help achieve higher quality of output by reducing the energy leakage between adjacent spectral bins. Such spectral decomposition and recombination is illustrated in FIG. 6. As shown in FIG. 6, a wideband input data stream X with group size L may be decomposed into L corresponding spectral band components Z using FFT circuit 410. Operated in this way, the FFT circuit 410 is configured to channelize the wideband input signal in the time domain into L orthogonal/independent components in the frequency domain. The independent components Z may then be processed by a multi-channel processing system 402 (e.g., circuit 402 shown in FIGS. 4 and 5) to produced processed components S. The iFFT circuit 420 may then convert the various processed spectral components back into the time domain to produce output stream Y.

The FFT/iFFT transformation may require a group length L of radix-2 (i.e., a group length that is a power of two). Thus, when using FFT/iFFT transforms, the group length L (sometimes referred to as frame length) should be configured based on the following expression:

L≥2̂(ceiling(log₂L_feedback)) (1)

where L_feedback represents the latency of the feedback path. Ideally, the group size L will be equal to the expression above for maximum throughput. In certain embodiments, one or more registers (see, e.g., registers 405 in FIG. 4) may be inserted in the feedback path to increase L_feedback so that it matches the group size. When this is achieve, there will be no dead or idle cycles at the processing circuit when processing the input data stream.

The example of FIG. 6 in which pre-processing circuit 410 performs FFT and post-processing circuit 420 performs iFFT is merely illustrative and is not intended to limit the scope of the present embodiments. In another suitable arrangement, circuit 410 may perform a discrete Fourier transform (DFT), whereas circuit 420 may perform an inverse Fourier transform (iDFT). In yet another suitable arrangement, circuit 410 may perform a wavelet transform, whereas circuit 420 may perform an inverse wavelet transform (iWT). If desired, any suitable type of orthogonal transforms and its inverse may be implemented around a recursive/iterative system.

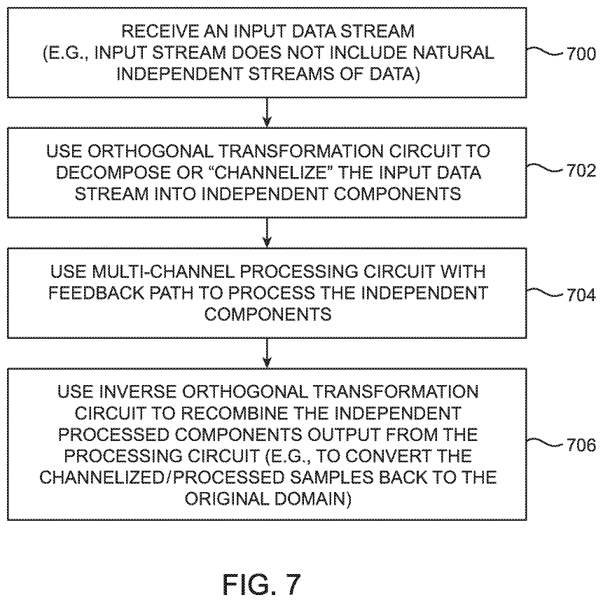

FIG. 7 is a flow chart of illustrative steps for operating a recursive system of the type shown in connection with FIGS. 4-6. At step 700, the recursive system may receive a single input data stream (e.g., an input stream that does not include natural independent streams of data).

At step 702, the orthogonal transformation circuit 410 (e.g., an FFT circuit, a DFT circuit, a wavelet transform circuit, etc.) may be used to decompose or channelize the input data stream into independent components.

At step 704, the multi-channel processing circuit (e.g., an iterative processing circuit having at least one feedback path with a feedback latency) may be used to process the independent components received from the orthogonal transformation circuit 410.

At step 706, the inverse orthogonal transformation circuit 420 (e.g., an iFFT, an iDFT circuit, an inverse wavelet transform circuit, etc.) may be used to recombine the processed components output from the multi-channel processing circuit (e.g., to convert the processed channelized samples back to the original domain).

Although the methods of operations are described in a specific order, it should be understood that other operations may be performed in between described operations, described operations may be adjusted so that they occur at slightly different times or described operations may be distributed in a system which allows occurrence of the processing operations at various intervals associated with the processing, as long as the processing of the overlay operations are performed in a desired way.

### EXAMPLES

The following examples pertain to further embodiments.

Example 1 is circuitry, comprising: an input configured to receive an input data stream; an orthogonal transformation circuit configured to receive the input data stream from the input and to decompose the input data stream into groups of independent components; and a processing circuit configured to receive the groups of independent components from the orthogonal transformation circuit.

Example 2 is the circuitry of example 1, wherein the processing circuit optionally has a feedback path with a feedback latency.

Example 3 is the circuitry of example 2, wherein the number of independent components in each of the groups is optionally a function of the feedback latency.

Example 4 is the circuitry of example 3, optionally further comprising: at least one register in the feedback path configured to balance the feedback latency with the number of independent components in each of the groups.

Example 5 is the circuitry of any one of examples 1-4, optionally further comprising: an inverse orthogonal transformation circuit configured to receive signals from the processing circuit and to recombine the signals into a corresponding output data stream.

Example 6 is the circuitry of example 5, wherein the orthogonal transformation circuit optionally comprises a fast Fourier transform (FFT) circuit.

Example 7 is the circuitry of example 6, wherein the inverse orthogonal transformation circuit optionally comprises an inverse fast Fourier transform (iFFT) circuit.

Example 8 is the circuitry of example 7, wherein the FFT circuit optionally comprises an analysis filter bank, and wherein the iFFT circuit optionally comprises a synthesis filter bank.

Example 9 is the circuitry of example 5, wherein the orthogonal transformation circuit optionally comprises a discrete Fourier transform circuit.

Example 10 is the circuitry of example 9, wherein the inverse orthogonal transformation circuit optionally comprises an inverse discrete Fourier transform circuit.

Example 11 is the circuitry of example 5, wherein the orthogonal transformation circuit optionally comprises a wavelet transform circuit, and wherein the inverse orthogonal transformation circuit optionally comprises an inverse wavelet transform circuit.

Example 12 is the circuitry of any one of examples 1-9, wherein the independent components generated by the orthogonal transformation circuit optionally comprise a plurality of independent spectral components in a frequency domain.

Example 13 is the circuitry of any one of examples 1-12, wherein there are no idle cycles at the processing circuit when processing the input data stream.

Example 14 is the circuitry of any one of examples 1-13, wherein the processing circuit optionally comprises a multi-channel processing circuit.

Example 15 is a method, comprising: receiving an input data stream; with an orthogonal transformation circuit, receiving the input data stream and decomposing the input data stream into a plurality of independent components; and with a processing circuit, receiving the plurality of independent components from the orthogonal transformation circuit and generating a plurality of processed components.

Example 16 is the method of example 15, wherein the input data stream optionally lacks independent streams of data.

Example 17 is the method of any one of examples 15-16, wherein the processing circuit optionally comprises a recursive circuit.

Example 18 is the method of any one of examples 15-17, optionally further comprising: with an inverse orthogonal transformation circuit, receiving the plurality of processed components from the processing circuit and recombining the plurality of processed components into a corresponding output data stream.

Example 19 is a system comprising: a recursive circuit having an input and an output; a pre-processing circuit that is coupled at the input of the recursive circuit and that is configured to channelize a wideband input signal into a plurality of independent spectral components; and a post-processing circuit that is coupled at the output of the recursive circuit and that is configured to reconstruct a wideband output signal based on the plurality of independent spectral components that have been processed by the recursive circuit.

Example 20 is the system of example 19, wherein the pre-processing circuit optionally comprises a transformation circuit selected from the group consisting of: a fast Fourier transform (FFT) circuit, a discrete Fourier transform circuit, and a wavelet transform circuit.

For instance, all optional features of the apparatus described above may also be implemented with respect to the method or process described herein. The foregoing is merely illustrative of the principles of this disclosure and various modifications can be made by those skilled in the art. The foregoing embodiments may be implemented individually or in any combination.

What is claimed is:

1. Circuitry, comprising:
an input configured to receive an input data stream;
an orthogonal transformation circuit configured to receive the input data stream from the input and to decompose the input data stream into groups of independent components; and
a processing circuit configured to receive the groups of independent components from the orthogonal transformation circuit.

2. The circuitry of claim 1, wherein the processing circuit has a feedback path with a feedback latency.

3. The circuitry of claim 2, wherein the number of independent components in each of the groups is a function of the feedback latency.

4. The circuitry of claim 3, further comprising:
at least one register in the feedback path configured to balance the feedback latency with the number of independent components in each of the groups.

5. The circuitry of claim 1, further comprising:
an inverse orthogonal transformation circuit configured to receive signals from the processing circuit and to recombine the signals into a corresponding output data stream.

6. The circuitry of claim 5, wherein the orthogonal transformation circuit comprises a fast Fourier transform (FFT) circuit.

7. The circuitry of claim 6, wherein the inverse orthogonal transformation circuit comprises an inverse fast Fourier transform (iFFT) circuit.

8. The circuitry of claim 7, wherein the FFT circuit comprises an analysis filter bank, and wherein the iFFT circuit comprises a synthesis filter bank.

9. The circuitry of claim 5, wherein the orthogonal transformation circuit comprises a discrete Fourier transform circuit.

10. The circuitry of claim 9, wherein the inverse orthogonal transformation circuit comprises an inverse discrete Fourier transform circuit.

11. The circuitry of claim 5, wherein the orthogonal transformation circuit comprises a wavelet transform circuit, and wherein the inverse orthogonal transformation circuit comprises an inverse wavelet transform circuit.

12. The circuitry of claim 1, wherein the independent components generated by the orthogonal transformation circuit comprise a plurality of independent spectral components in a frequency domain.

13. The circuitry of claim 1, wherein there are no idle cycles at the processing circuit when processing the input data stream.

14. The circuitry of claim 1, wherein the processing circuit comprises a multi-channel processing circuit.

15. A method, comprising:
receiving an input data stream;
with an orthogonal transformation circuit, receiving the input data stream and decomposing the input data stream into a plurality of independent components; and
with a processing circuit, receiving the plurality of independent components from the orthogonal transformation circuit and generating a plurality of processed components.

16. The method of claim 15, wherein the input data stream lacks independent streams of data.

17. The method of claim 15, wherein the processing circuit comprises a recursive circuit.

18. The method of claim 15, further comprising:
with an inverse orthogonal transformation circuit, receiving the plurality of processed components from the processing circuit and recombining the plurality of processed components into a corresponding output data stream.

19. A system comprising:
a recursive circuit having an input and an output;
a pre-processing circuit that is coupled at the input of the recursive circuit and that is configured to channelize a wideband input signal into a plurality of independent spectral components; and
a post-processing circuit that is coupled at the output of the recursive circuit and that is configured to reconstruct a wideband output signal based on the plurality of independent spectral components that have been processed by the recursive circuit.

20. The system of claim 19, wherein the pre-processing circuit comprises a transformation circuit selected from the group consisting of: a fast Fourier transform (FFT) circuit, a discrete Fourier transform circuit, and a wavelet transform circuit.
